(19) United States
(12) Patent Application Publication
(10) Pub. No.: US 2010/0079021 A1
(43) Pub. Date: Apr. 1, 2010

(54) Housing Comprising An Air Flow Conduit Preventing All Liquid Accumulation

(75) Inventor: Hervé Lorin, Poitiers (FR)

Correspondence Address: OSHA LIANG L.L.P., TWO HOUSTON CENTER, 909 FANNIN, SUITE 3500, HOUSTON, TX, 77010, US

(73) Assignee: Valeo Systemes d'Essuyage, La Verriere (FR)

(21) Appl. No.: 10/553,335

(22) PCT Filed: Apr. 14, 2004
(86) PCT No.: PCT/EP04/03912

§ 371 Date: May 31, 2007

(30) Foreign Application Priority Data
Apr. 16, 2003 (FR) 03/04791

(51) Int. Cl. H02K 5/12; H05K 5/06

(52) U.S. Cl. 310/88; 174/17.06

(57) ABSTRACT

A liquid tightly sealed housing has an electrical or electronic device arranged in an internal volume of the housing, a channel with a globally vertical main axis, passing through an upper wall of the housing to connect the internal volume of the housing to outside, and closure apparatuses for making the channel liquid-tight and gas-permeable. The closure apparatuses are arranged at least partly on the upper wall of the housing and at an upper end of the channel so as to prevent any liquid accumulation in the channel.

The invention provides a housing for an electronic and/or electrical device, such as for example, the control system of an electric motor, which is sealed in a liquid-tight, air-permeable manner.

The invention provides, more specifically, a hermetically sealed housing in the internal volume of which is arranged an electronic or electrical device, of the type comprising a channel with a globally vertical main axis passing through an upper wall of the housing to connect the internal volume of the housing with the outside, and of the type comprising closure means for making the channel liquid-tight and gas-permeable.

Electronic and/or electrical devices, such as, for example, the electronic calculator of an internal-combustion engine, or the control system of an electric motor for driving a wiping mechanism, are sometimes arranged inside the engine compartment of the motor vehicle they equip.

These devices are particularly sensitive to projections of liquids and to dust, which is why they are generally arranged inside a hermetically sealed housing.

While being used, an electronic device heats itself and the air contained inside the housing, which causes an expansion, and therefore an increase of the air pressure. Although the housing is hermetically sealed, some of the expanded air escapes to the outside of the housing, mainly due to the pressure difference between the inside and the outside of the housing.

When the electronic device is in idle mode, its temperature drops, as does the temperature of the air contained inside the housing. This also causes the pressure inside the housing to fall. Air from outside then enters the housing.

The outside air is generally charged with moisture, which accumulates and condenses inside the housing as the operational and idle phases of the electronic device are repeated. The condensed water thus accumulated is a potential source of short-circuits and oxidation of the components of the electronic device, which can greatly harm its operation.

In order to prevent this accumulation of moisture inside the case, housings are provided that comprise a so-called “breather” system, which enables air to flow between the inside of the housing and the outside, and thus to maintain a balance of the pressures, while preventing an accumulation of moisture inside the housing.

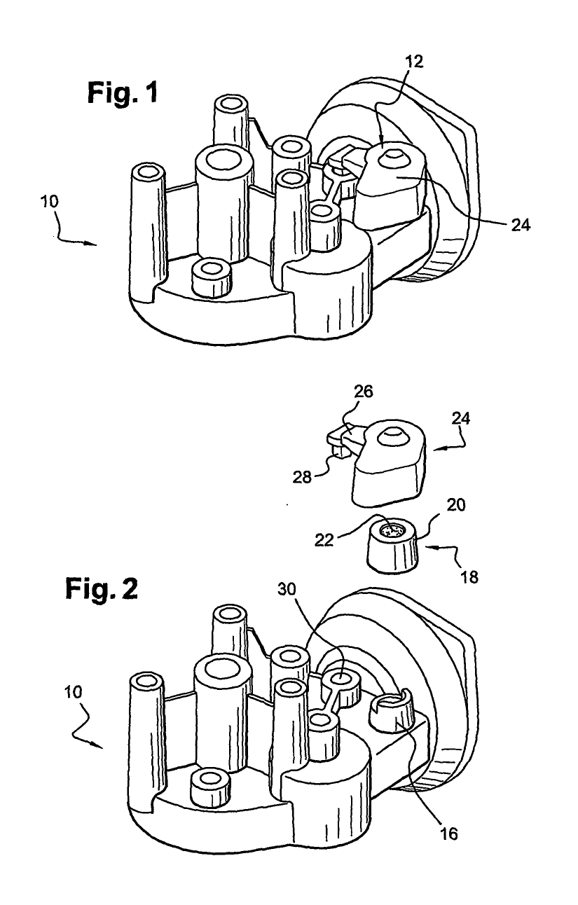

FIGS. 1 and 2 show an element or body 10 of the housing of a device for driving a wiping mechanism, which comprises a breather 12 according to a known embodiment.

The breather 12 comprises a channel 14 that passes through the body 10 to connect the internal volume of the housing with the outside, and which is extended outwards by means of a cone-shaped conduit 16.

The breather 12 also comprises a closure nozzle for making the channel 14 liquid-tight and air-permeable.

The nozzle 18 comprises a sleeve 20 that covers the cone-shaped conduit 16 and which is attached to the latter using standard means such as, for example, bell-shaped joining or gluing, in order for the link between the sleeve 20 and the cone-shaped conduit 16 to be hermetic. The sleeve 20 has a membrane 22 at the height of its upper end, which passes through the channel 14. The membrane 22 is made from an air-permeable, watertight material such as, for example, the fabric known by the trademark “GORE-TEX®”.

The wiping mechanism connected to the front windscreen wiper of a motor vehicle is generally arranged under the bonnet of the vehicle, in a compartment called “header tank”.

In general terms, this compartment is open and communicates with the outside by means of protective grids made in the bonnet of the vehicle, which prevent large objects, mainly leaves or gravel, from entering the compartment. However, these protective grids do not stop liquids from entering the compartment.

Thus, according to the layout of the wiping mechanism in the compartment, the breather may be exposed to projections of liquids. When these liquids reach the breather 12 at a high speed, which is the case, for example, when users clean their vehicles using a high-pressure cleaner, there is the risk of seriously damaging the membrane 22.

This is why the breather 12 is connected to a hood 24 that covers the nozzle 18 in order to prevent elements from being projected directly onto the membrane 22.

The hood 24 is fixed to the body 10 by means of a lug 26 comprising a finger 28 that can be inserted in a complementary housing 30 on the body 10.

Although this breather provides perfect insulation of the internal volume of the housing, it has a considerable number of parts, and assembling these parts entails a relatively complex process, since it requires the parts to be precisely placed in relation to the body 10.

Documents FR-A-2.758.873 and U.S. Pat. No. 5,894,180 describe other embodiments for breathers according to which the membrane is fixed to the body, across the channel connecting the inside of the housing with the outside, and protected from possible projections by means of a protective cover.

According to these embodiments, the breather is relatively simple in terms of design. However, water can accumulate in the channel and cover the outer face of the membrane entirely, thus preventing the airflow between the inside of the housing and the outside.

The invention aims to provide a housing that comprises a breather with a relatively simple design, and which makes it possible to avoid all liquid accumulation on the outer face of the membrane.

To this end, the invention provides a housing of the type described previously, characterised in that the closure means are arranged at least partly on the upper wall of the housing and at the height of the upper end of the channel, in order to prevent any liquid accumulation inside the channel.

According to further characteristics of the invention:
the closure means comprise a liquid-tight, gas-permeable membrane, which extends globally horizontal so as to close off the channel;
the membrane is fixed to the outer face of the upper wall, projecting upwards from the upper wall;
the closure means comprise a cover that is fixed to the outer face of the upper wall, such as to extend above the upper end of the channel;
the cover extends at a distance from the upper end of the channel;
the cover comprises a plate that extends horizontally globally parallel to the upper wall, the lower face of which, opposite the upper end of the channel, has a vertical finger that is inserted partly in the channel.
the upper wall comprises an annular rib that extends vertically upwards in order to extend the channel, and the cover comprises an annular ring that is coaxial to the rib, the inner diameter of which is greater than the outer diameter of the rib, which extends vertically downwards from the lower face of the plate;
the ring comprises at least one groove that extends vertically upwards from the lower edge of the free end of the ring towards the lower face of the plate;
the membrane is fixed to the internal face of the upper wall;
the upper wall comprises an orifice that is crossed by electrical connection means for the electronic device, linked to an external power supply which is fixed to the upper wall of the housing;
the cover is supported by the connector.

Other characteristics and advantages of the invention will become apparent from reading the following detailed description, which is made in relation to the attached figures, in which:

FIG. 1 is a schematic view in perspective of a housing comprising a breather according to a previous embodiment;

FIG. 2 is a similar view to that in FIG. 1, in which the breather is shown exploded;

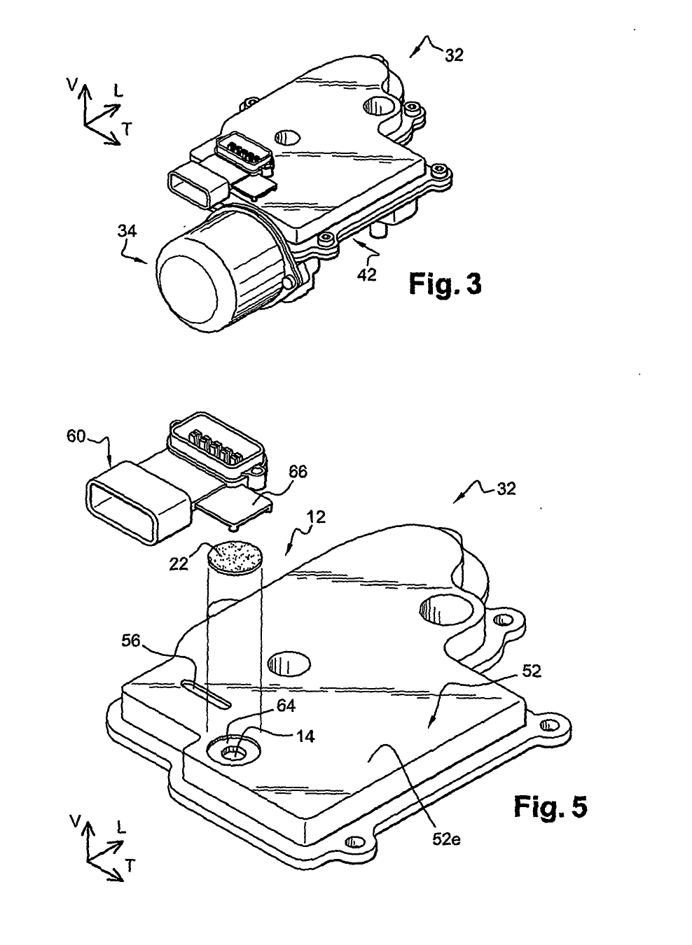

FIG. 3 is a schematic view in perspective of a driving device comprising a breather according to the invention;

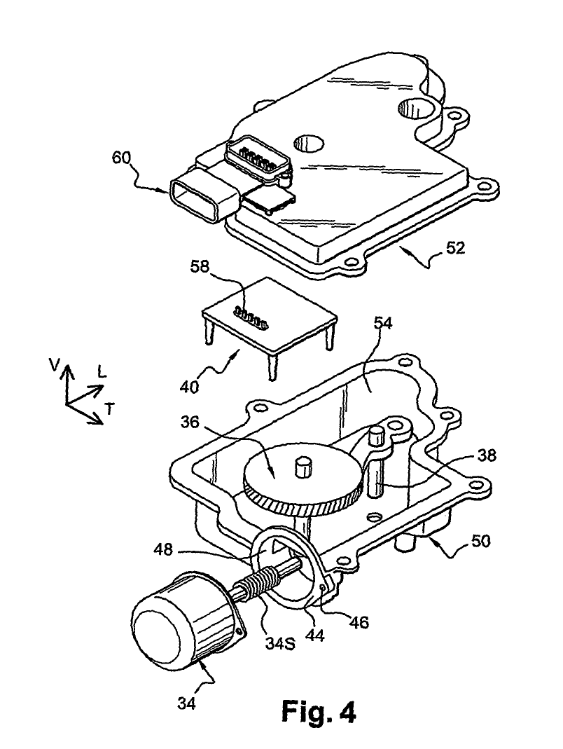

FIG. 4 is an exploded schematic view of the driving mechanism shown in FIG. 3;

FIG. 5 is an exploded view on a larger scale of the breather shown in FIG. 3;

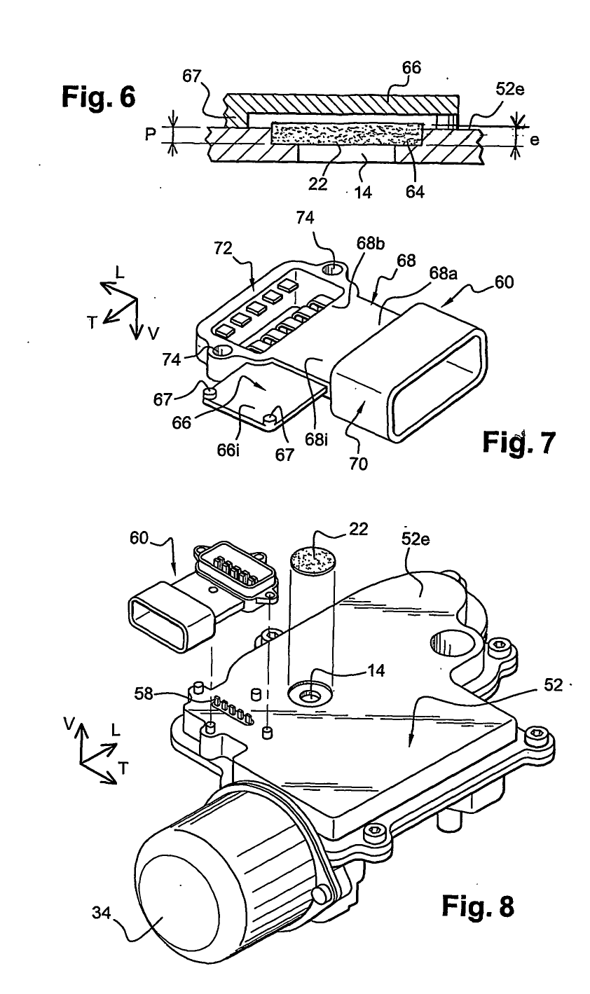

FIG. 6 is a transverse section of the breather shown in FIG. 3;

FIG. 7 is a detail of a bottom view of the connector according to the embodiment shown in FIG. 5;

FIG. 8 is a view similar to that shown in FIG. 5, showing an alternative embodiment of the invention;

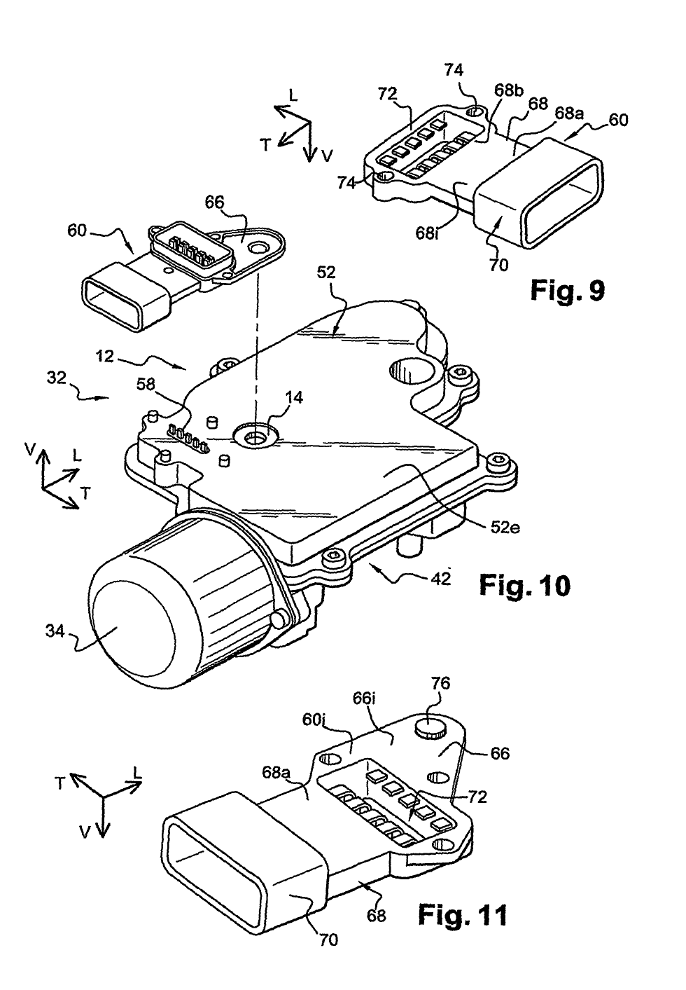

FIG. 9 is a detail of a bottom view of the connector according to the alternative embodiment shown in FIG. 8;

FIG. 10 is a view similar to that shown in FIG. 3, showing another embodiment of the breather according to the invention;

FIG. 11 is a similar view to that shown in FIG. 9, of the connector according to the embodiment shown in FIG. 10;

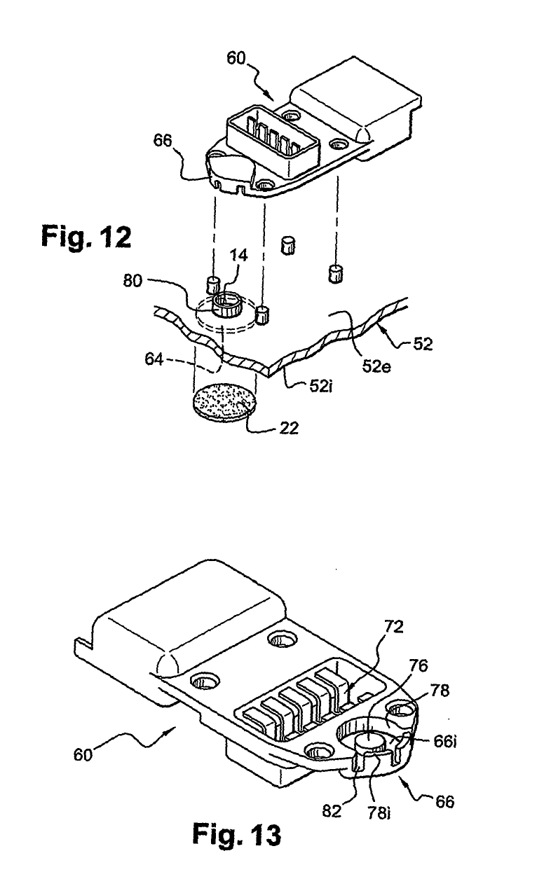

FIG. 12 is a similar view to that shown in FIG. 3, showing yet another embodiment of the breather according to the invention;

FIG. 13 is a similar view to that shown in FIG. 9, of the connector according to the embodiment shown in FIG. 12.

For the description of the invention, the vertical, longitudinal and transverse orientations will be referred to with the markers V, L and T shown in the figures.

In addition, the back-to-front orientation will be used to refer to the longitudinal direction, from right to left in relation to FIG. 3.

In the following description, identical, similar or analogue elements will be referred to using the same reference numbers.

FIGS. 3 and 4 show a driving device 32 for a windscreen-wiper mechanism (not shown) which comprises an electric motor 34, a mechanism 36 for transforming the continuous rotation movement from the output shaft 34s of the motor 34 into an alternating rotation movement of a driving shaft 38, which will subsequently be called reducing gear, and an electronic control device 40 for the motor 34.

The driving device 32 also comprises a housing 42 in the interior of which are arranged the electronic device 40 and the reducing gear 36. The housing 42 comprises means for attaching the motor 34, which consist in this case of an annular flange 44 and threaded holes 46 arranged around an orifice 48 which the output shaft 34s of the motor 34 passes through, and means for attaching the driving device 32 to a structural element of the vehicle body.

The housing 42 comprises a lower shell 50 which includes means (not shown) for supporting the reducing gear 36 and the electronic device 40; it comprises an orifice (not shown) which the driving shaft 38 passes through, and the means for attaching the driving motor 34 to the housing 42.

The housing 42 also includes a closing plate 52, which defines, together with the lower shell 50, the internal volume 54 of the housing 42.

The closing plate 52 comprises an orifice 56, which the tabs for electrical connection 58 of the electronic device 40 to an external power supply 60, which is attached to the closing plate 52, pass through.

The housing 42 is sealed in a liquid-tight, air-permeable manner. For this purpose, the lower shell 50 is hermetically attached to the driving motor 34 and to the closing plate 52, and the orifices that the driving shaft 28 and the connection tabs 58 pass through are sealed by known hermetic means, mainly made from rubber.

Finally, the housing 42 comprises means 12 that form a “breather” that allows air to flow between the internal volume 54 of the housing 42 and the outside, which are arranged on the closing plate 52.

As can be seen in greater detail in FIG. 5, the breather 12 comprises a channel 14 with a vertical main axis passing through the closing plate 52 to connect the internal volume 54 of the housing 42 with the outside, and a membrane 22 that closes the channel off in a way that is liquid-tight and gas-permeable. The membrane 22 is made, for example, from the material known by the trademark GORE-TEX®.

The membrane 22 closes off the channel 14, in other words, it extends globally horizontally, and it is fixed to the closing plate 52 using known means, mainly by gluing.

There are known ways of arranging the membrane 22 on the internal face of the closing plate 52, or in the channel 14 at an intermediate vertical height. In this way, water can accumulate in the channel 14, and completely cover the membrane 22. This results in complete blocking of the channel 14.

This is why, according to the invention, the membrane 22 is arranged on the closing plate 52 in order to prevent all water accumulation in the channel 14.

For this purpose, the membrane 22 is arranged in order to project upwards in relation to the external face 52e of the closing plate 52.

According to a first embodiment, the membrane 22 is attached directly on the external face 52e of the closing plate 52. However, the surface of the external face 52e of the closing plate 52 may be of poor quality, due to the process used to produce the closing plate 52.

This is why, according to a preferred embodiment of the invention, and as shown in FIGS. 5 and 6, the closing plate 52 comprises a counterbore 64 which is coaxial to the channel 14 and which extends vertically downwards from the external face 52e of the closing plate 52, and which has a depth “p” that is less than the thickness “e” of the membrane 22.

According to another embodiment of the invention (not shown), the closing plate 52 comprises a boss that is coaxial to the channel 14, which extends vertically upwards from the external face 52e of the closing plate 52, the upper face of which is designed, for example by machining, in order to receive the membrane 22.

According to the layout of the driving mechanism 32 in relation to the vehicle, it is possible for the membrane 22 to be arranged near an opening made in the bonnet of the vehicle. The membrane 22 is therefore exposed to projections of water that can damage it.

In order to protect the membrane 22 from the projections of water, and according to another aspect of the invention, the means that form the breather 12 comprise a cover 66 that extends horizontally over the membrane 22.

The cover 66 extends at a distance from the membrane 22 in order to allow air to flow through the membrane 22. For this purpose, the cover 66 comprises feet 67 to support it against the external face 52e of the closing plate 52.

According to a preferred embodiment of the invention, and as can be seen in FIGS. 4 to 6, the cover 66 is formed integral with the connector 60.

Thus, it is not necessary to provide means for attaching the cover 66 to the closing plate 52, since they are already provided by the means for attaching the connector 60 to the closing plate 52.

In addition, this makes it possible to connect the same driving mechanism 32 to two types of connectors 60, comprising a cover 66 or not, without requiring any modification of the means for fixing the connector 60 to the closing plate 52 being required.

A connector 60 comprising a cover 66 according to the invention is shown in FIG. 7, and it comprises a central body 68 with a conventional structure, which extends globally horizontally, a rear longitudinal end 68a of which includes means 70 for attaching an electrical power supply cable (not shown), the front longitudinal end 68b including means 72 for electrically connecting the power cable to the connection tabs 58.

When the connector 60 is attached to the housing 42, the lower face 68i of the body 68 is resting against the upper face 52e of the closing plate 52. Furthermore, the connector comprises vertical orifices 74 that are suited for receiving fingers for attaching, as shown mainly in FIG. 8, the connector 60 to the closing plate 52.

The cover 66 is formed integral with the body 68 of the connector, and it extends transversally from the lateral edge of the body 68.

As mentioned previously, the cover 66 extends over the membrane 22, and the membrane 22 projects upwards from the upper face 52e of the closing plate 52. Thus, the lower face 66i of the cover 66 is shifted vertically upwards in relation to the lower face 68i of the body 68.

Finally, to prevent the awkwardly positioned free end of the cover 66 from coming into contact with the membrane 22, or the upper face 52e of the closing plate 52, the cover 66 comprises support feet 67 extending vertically downwards from the lower face 66i of the cover 66.

The channel 14 is positioned on the closing plate in order to extend under the cover 66 when the connector 60 is in the mounted position on the closing plate 52. Here, the channel is shifted transversally in relation to the connector 60.

FIG. 8 shows another embodiment of the invention according to which there are no means for protecting the membrane 22 against projections of liquid.

This embodiment is preferably used when the driving mechanism 32 is arranged in a compartment that is sufficiently sealed such as to prevent projections of water from reaching the membrane 22.

As shown in FIG. 9, the connector 60 is therefore a standard connector that does not have any particular adjustments and that does not comprise any elements of the breather 12.

The channel 14 is shifted longitudinally forwards in relation to the connector 60; however, it can be positioned anywhere on the closing plate 52 without departing from the field of the invention.

The channel 14 in this case is blocked by a membrane 22 that is fixed to the closing plate 52 so as to project upwards from the external face 52e of the closing plate 52, as described previously.

FIG. 10 shows a housing 42 with a closing plate 52 that is identical to that of the embodiment shown in FIG. 8, in other words, the channel 14 is shifted longitudinally forwards in relation to the connector 60 when the latter is in the mounted position. However, according to this embodiment, the channel 14 is blocked only by a cover 66.

As can be seen in greater detail in FIG. 11, the cover 66 extends longitudinally forwards from the front longitudinal end 68a of the body 68, so that its lower face 66i can be flush with the lower face 60i of the connector 60, in order to be in contact with the external face 52e of the closing plate 52.

The cover 66 also comprises a vertical finger 76 that extends vertically downwards from the lower face 66i of the cover 66, coaxially to the channel 14.

When the connector 60 is in the mounted position on the closing plate 52, the vertical finger 76 extends inside the channel 14, and its outer diameter is slightly smaller than the inner diameter of the channel 14, in order to prevent external elements from entering the internal volume 54 of the housing 42.

The breather 12 thus described allows air to flow between the internal volume 54 of the housing 42 and the outside; however, it does not allow the channel 14 to be closed off in a way that is liquid-tight.

Thus, the same structure of the closing plate 52 can be used in combination with a breather 12 according to any of the previously described embodiments, in other words, comprising a membrane 22 and a cover 66, as shown in FIG. 5, using only the membrane 22, as shown in FIG. 8, or using only a cover 66, as shown in FIG. 10.

The choice of a breather 12 is made according to technical constraints brought about by the arrangement of the driving mechanism 32 in relation to the vehicle body structure element, or else according to economic constraints due to the high cost of a membrane 22.

FIGS. 12 and 13 show another embodiment of the invention, according to which the channel 14 is blocked by a membrane 22 which is fixed to the internal wall 52i of the closing plate 52.

In order to prevent water from accumulating inside the channel 14, the closing plate 52 comprises an annular rib 78 that extends vertically upwards as an extension of the channel 14. Thus, the water that accumulates on the external face 52e of the closing plate 52 cannot enter the channel 14 by streaming.

To prevent water from entering the channel 14 by projection, the rib 78 is covered with a cover 66 and, according to a preferred embodiment of the invention, the cover 66 is supported by the connector 60.

As can be seen in greater detail in FIG. 13, the cover 66 has a vertical finger 76 that extends vertically downwards from the lower face 66i of the cover 66, so as to enter the channel 14 when the cover 66 is in its mounted position on the closing plate 52.

The cover 66 also comprises an annular ring 80 that is coaxial to the rib 78 so that, when the cover 66 is in the mounted position on the closing plate 52, the ring 80 can cover the rib 78.

The unit made up of the rib 78, the vertical finger 76 and the ring 80 makes up a complex passage in the manner of a “double bend”, which prevents all solid and liquid polluting elements from entering the channel 14.

The driving mechanism 32 has been described as being positioned so that the closing plate 52 can define the upper wall of the housing 42, in other words, so that it extends above the lower shell 50. This layout is generally used when the driving shaft 38 is connected to several wiping blades, by means of a series of rods, that are not shown.

However, it is possible for the driving shaft 38 to be connected directly to a wiper blade. For this, it is necessary to arrange the driving mechanism 32 in order for the closing plate 52 to extend under the lower shell 50, in other words, for the driving shaft 32 to extend vertically upwards.

The channel 14 is thus oriented downwards, the rib 78 and the lower face 66i of the cover 66 thus define a cup in which the water can accumulate, and thus completely block the channel 14.

In order to prevent water from accumulating in this cup, the rib 78 comprises several grooves 82 that extend vertically from the free lower edge 78i of the rib towards the lower face 66i of the cover.

Then, when the driving mechanism 32 is oriented so that the driving shaft 38 extends upwards, any water that might have accumulated in the cup, runs away through the grooves 82.

The cover 66 has been described as an element formed integral with the connector 60. However, it shall be understood that the invention is not limited to this embodiment, and that the cover 66 can be an independent element from the connector 60, which is fixed to the closing plate 52, without departing from the technical field of the invention.

It shall also be understood that simple mechanical inversions can constitute alternative embodiments of the invention. For example, the breather can be arranged on the lower shell 50.

However, the closing plate 52 consists of a globally flat element, which makes it easier to place the channel 14 and, if required, the counterbore 64 in the closing plate than in the lower shell.

1. A liquid tightly sealed housing comprising:
an electrical or electronic device arranged in an internal volume of the housing
a channel with a globally vertical main axis, passing through an upper wall of the housing to connect the internal volume of the housing to the outside, and
closure means for making the channel liquid-tight and gas-permeable,
wherein the closure means are arranged at least partly on the upper wall of the housing and at an upper end of the channel so as to prevent any liquid accumulation in the channel.

2. The housing according to claim 1, wherein the closure means comprise a membrane that is liquid-tight and gas-permeable, which extends globally horizontally in order to close off the channel.

3. The housing according to claim 2, wherein the membrane is fixed to an external face of the upper wall, projecting upwards in relation to the upper wall.

4. The housing according to claim 2, wherein the closure means comprise a cover that is fixed to an external face of the upper wall so as to extend above the upper end of the channel.

5. The housing according to claim 4, wherein the cover extends at a distance from the upper end of the channel.

6. The housing according to claim 5, wherein the cover comprises a plate that extends horizontally globally parallel to the upper wall and a lower face of the plate, opposite the upper end of the channel, has a vertical finger that is inserted partly in the channel.

7. The housing according to that claim 6, wherein the upper wall comprises an annular rib that extends vertically upwards so as to extend the channel, and the cover comprises an annular ring that is coaxial with the rib, has an inner diameter that is greater than an outer diameter of the rib, which and extends vertically downwards from the lower face of the plate.

8. The housing according to claim 7, wherein the ring comprises at least one groove that extends vertically upwards from a lower edge of a free end of the ring until the lower face of the plate.

9. The housing according to claim 7, wherein the membrane is fixed to an internal face of the upper wall.

10. The housing according to claim 1, further comprising electrical connection means for linking the electronic device to an external power supply connector fixed to the upper wall of the housing, wherein the upper wall comprises an orifice, and the electrical connection means pass through the orifice.

11. The housing according to claim 10, wherein the closure means comprise a cover that is fixed to an external face of the upper wall so as to extend above the upper end of the channel, and the cover is supported by the connector.

12. An electric motor for driving a wiping mechanism comprising a the housing according to claim 1.

13. (canceled)

14. The housing according to claim 3, wherein the closure means comprise a cover that is fixed to an external face of the upper wall so as to extend above the upper end of the channel.

15. The housing according to claim 4, wherein the closure means comprise a cover that is fixed to an external face of the upper wall so as to extend above the upper end of the channel.

16. The housing according to claim 8, wherein the membrane is fixed to an internal face of the upper wall.

17. The housing according to claim 9, further comprising electrical connection means for linking the electronic device to an external power supply connector fixed to the upper wall of the housing, wherein the upper wall comprises an orifice, and the electrical connection means pass through the orifice.

18. An electric motor for driving a wiping mechanism comprising the housing according to claim 11.
